(19) United States
(12) Patent Application Publication
(10) Pub. No.: US 2007/0091674 A1
(43) Pub. Date: Apr. 26, 2007

(54) TRANSISTOR AND METHOD OF FABRICATION

(75) Inventors: Human Park, LaGrangeville, NY (US); Philippe Blanchard, Moigny sur Ecole (FR); Woosik Kim, Boissettes (FR); Gill Yong Lee, Boissise-le-Roi (FR)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/536,323

(22) Filed: Sep. 28, 2006

(30) Foreign Application Priority Data
Sep. 29, 2005 (DE) 10 2005 046 739.3

(51) Int. Cl. G11C 11/14

(52) U.S. Cl. 365/171

(57) ABSTRACT

A transistor cell and method of making a transistor cell is disclosed. In one embodiment a transistor cell, includes first metal line spacers and the first gate spacers that vertically at least partially overlap, wherein second metal line spacers and second gate spacers vertically at least partially overlap. A contact region is defined above a second source/drain region and/or a third source/drain region by a respective adjacent first metal line spacer and second metal line spacer and by a respective adjacent first gate spacer and second gate spacer. A contact via vertically extends from the contact region at least to the layer of the first metal line.

### CROSS REFERENCE TO RELATED APPLICATIONS

This Utility Patent Application claims priority to German Patent Application No. DE 10 2005 046 739.3 filed on Sep. 29, 2005, which is incorporated herein by reference.

### FIELD OF THE INVENTION

This invention relates to semiconductor structures, and more particularly, to a method of forming quasi self-aligned contacts in magnetic random access memory (MRAM) structures.

### BACKGROUND OF THE INVENTION

Magnetic (or magneto-resistive) random access memory (MRAM) is a non-volatile access memory technology that could potentially replace the dynamic random access memory (DRAM) as the standard memory for computing devices. Particularly, the use of MRAM-devices as a non-volatile RAM will eventually allow for “instant on”-systems that come to life as soon as the computer system is turned on, thus saving the amount of time needed for a conventional computer to transfer boot data from a hard disk drive to volatile DRAM during system power up.

A magnetic memory element (also referred to as a tunnelling magneto-resistive or TMR-device) includes a structure having ferromagnetic layers separated by a non-magnetic layer (barrier) and arranged into a magnetic tunnel junction (MTJ). Digital information is stored and represented in the magnetic memory element as directions of magnetization vectors in the ferromagnetic layers. More specifically, the magnetic moment of one ferromagnetic layer is magnetically fixed or pinned (also referred to as “fixed layer” or “reference layer”), while the magnetic moment of the other ferromagnetic layer (also referred to as “free layer”) is free to be switched between the parallel and anti-parallel magnetization directions with respect to the fixed magnetization direction of the reference layer by application of electric currents. These currents are typically applied through conductive write lines referred to as bit lines and word lines, which are disposed so that the bit lines are orthogonal to the word lines. In an MRAM array, an MTJ memory cell is located at each intersection of a bit line with a word line.

In a typical MTJ cell, to switch the direction of magnetization of the free layer of a particular cell, currents are applied through the bit line and the word line that intersect at that cell. The direction of these currents determines the direction in which the magnetization of the free layer will be set. The combined magnitude of the currents through the word and bit lines must be sufficient to generate a magnetic field at their intersection that is strong enough to switch the direction of magnetization of the free layer.

One difficulty with such MRAM designs is that because a magnetic field is used to write the cells, there is a risk of inadvertently switching memory cells that are adjacent to the targeted memory cell, due, for example, to inconsistencies in the magnetic material properties of the cells. Additionally, any memory cells located along the same word or bit line as the selected cell is subject to a portion of the magnetic switching field, and may be inadvertently switched. Other causes of undesired switching of cells may, for example, include fluctuations in the magnetic field, or alterations in the shape of the field.

In MRAM designs known as thermal select MRAMs, these difficulties are addressed by thermal heating. A heating current is applied to reduce the saturation magnetization for the selected cells. Using this method, only the heated cells can be switched, reducing the occurrence of inadvertent cell switching. In some designs, this heating may be achieved by passing a current through the barrier layer of a cell, the resistance of which heats the cell.

Another type of MRAM that addresses these difficulties uses current-induced spin transfer to switch the free layer of the MTJ. In such “spin-injection” MRAM, the free layer is not switched via application of a magnetic field generated by the bit lines and word lines. Instead, a write current is forced directly through the MTJ to switch the free layer. The direction of the write current through the MTJ determines whether the MTJ is switched into a “0” state or a “1” state. A select transistor connected in series with the MTJ may be used to select a particular cell for a write operation.

Another difficulty that is encountered in MRAM is the size of the cells. In the current highly competitive market for memory devices, it is necessary to achieve high density by minimization of cell size. Unfortunately, in many MRAM designs, it is very difficult to reduce the cell size to compete with other types of memory devices. This has several causes. First, MRAM cells generally require a drastically higher write current than conventional DRAM (Dynamic Random Access Memory), particularly when thermal select MRAM or spin injection MRAM is being used. Since the write current is limited by the transistor dimensions in a cell, the transistor dimensions may have to be relatively large in MRAM devices.

Additionally, features such as the size of the individual source/drain contacts and via connections to a metal line for each memory cell are large contributors to the size of cells in many MRAM designs. In particular the width of the via connections are conventionally smaller than design rule limitations, since they are limited by photolithographic definition, also referred to as mask definition. Thus, the contact size itself can not be scaled down below the design rule limits and a substantial reduction of the cell size cannot be achieved.

Similar difficulties with cell size are encountered in other recent memory technologies, such as phase-change random access memories (PCRAM), in which data are written by using ohmic heating to change the phase of a material between an amorphous and a crystalline state. The heating operation in such PCRAM requires a relatively high write current, leading to difficulties similar to those encountered with MRAM.

What is needed in the art is a design for memory cells for high-write current memory technologies, such as MRAM, with reduced cell size.

### SUMMARY

One embodiment provides a transistor cell, including a first transistor having a first source/drain region, a first gate region, a second source/drain region and first gate spacers adjacent to the first gate region, a second transistor having a third source/drain region, a second gate region, a fourth source/drain region and second gate spacers adjacent to the second gate region, wherein the second source/drain region and the third source/drain region are connected with each other, a first metal line above the first transistor, first metal line spacers adjacent to the first metal line, a second metal line above the second transistor, second metal line spacers adjacent to the second metal line, wherein the first metal line spacers and the first gate spacers vertically at least partially overlap, wherein the second metal line spacers and the second gate spacers vertically at least partially overlap, wherein a contact region is defined above the second source/drain region and/or the third source/drain region by a respective adjacent first metal line spacer and second metal line spacer and by a respective adjacent first gate spacer and second gate spacer, a contact via vertically extending from the contact region at least to the layer of the first metal line.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 illustrates a perspective view of a conventional MRAM array.

FIGS. 2A and 2B illustrate, respectively, a block diagram and a sample layout of a conventional thermal select MRAM cell.

FIG. 3 schematically illustrates the method, disclosed by J. H. Park et al. at the IEDM in 2003, of forming an 8 F² cell in 180 nm technology node for conventional Stoner Wohlfarth MRAM.

FIGS. 4A and 4B illustrate an embodiment of a thermal select MRAM cell.

FIG. 5 illustrate a perspective view of the memory cell illustrated in FIGS. 4A and 4B.

FIG. 6 illustrates a cross section of the memory cell design described in FIG. 4A, FIG. 4B and FIG. 5, illustrating the self-aligned via contacts of the two-transistor design.

### DETAILED DESCRIPTION OF EXEMPLARY EMBODIMENTS

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

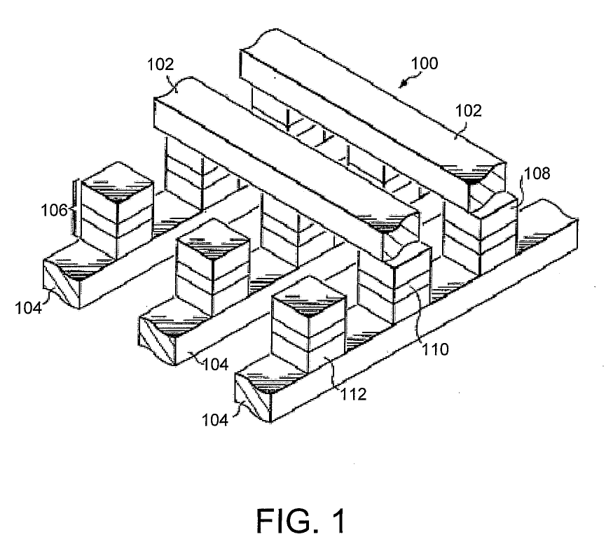

FIG. 1 illustrates a perspective view of a conventional art MRAM array 100 having bit lines 102 disposed in an orthogonal direction to word lines 104 in adjacent metallization layers. Magnetic memory stacks 106 are electrically coupled to the bit lines 102 and word lines 104 (collectively, write lines), and are positioned between the bit lines 102 and word lines 104 at locations where a bit line 102 crosses a word line 104. The magnetic memory stacks 106 are preferably magnetic tunnel junctions (MTJs), having multiple layers, including a free layer 108, a tunnel layer 110, and a fixed layer 112. The free layer 108 and fixed layer 112 preferably include a plurality of magnetic metal layers (not illustrated). These magnetic metal layers may, for example, include eight to twelve layers of materials such as PtMn, CoFe, Ru, and NiFe. The tunnel layer 110 includes a dielectric, such as Al₂O₃.

In one embodiment, the fixed layer 112 is magnetized in a fixed direction, while the direction of magnetization of the free layer 108 may be switched, changing the resistance of the magnetic memory stack 106. One bit of digital information may be stored in a magnetic memory stack 106 by running a current in the appropriate direction through the bit line 102 and the word line 104 that intersect at the magnetic memory stack 106, creating a sufficient magnetic field to set the direction of magnetization of the free layer 108. Information may be read from a magnetic memory stack 106 by applying a voltage across the magnetic memory stack, and measuring the resistance. If the direction of magnetization of the free layer 108 is parallel to the direction of magnetization of the fixed layer 112, then the measured resistance will be low, representing a value of “0” for the bit. If the direction of magnetization of the free layer 108 is anti-parallel to the direction of magnetization of the fixed layer 112, then the resistance will be high, representing a value of “1”.

It will be understood that the view illustrated in FIG. 1 is simplified, and that actual MRAM devices may include additional components. For example, in some MRAM designs, a transistor is coupled to each magnetic memory stack 106, for isolation. It will further be recognized that the view illustrated in FIG. 1 represents only a small portion of an actual MRAM device. Depending on the organization and memory capacity of the device, there may be hundreds or thousands of bit lines and word lines in a memory array. For example, a 1 Mb MRAM device (i.e., an MRAM device storing approximately one million bits of data) may include two arrays, each of which has 1024 word lines and 512 bit lines. Additionally, in some MRAM devices, there may be multiple layers of magnetic memory stacks, in which layers may share bit lines or word lines.

Variations in the MRAM technology in use may also lead to some variation in the basic design illustrated in FIG. 1. For example, in a typical thermal select MRAM, each cell includes a transistor (not illustrated) coupled between the MTJ and ground. The word line may be used to select the cell by being electrically connected to the gate of the transistor, so that a heating current flows through the cell from the bit line when the transistor is selected.

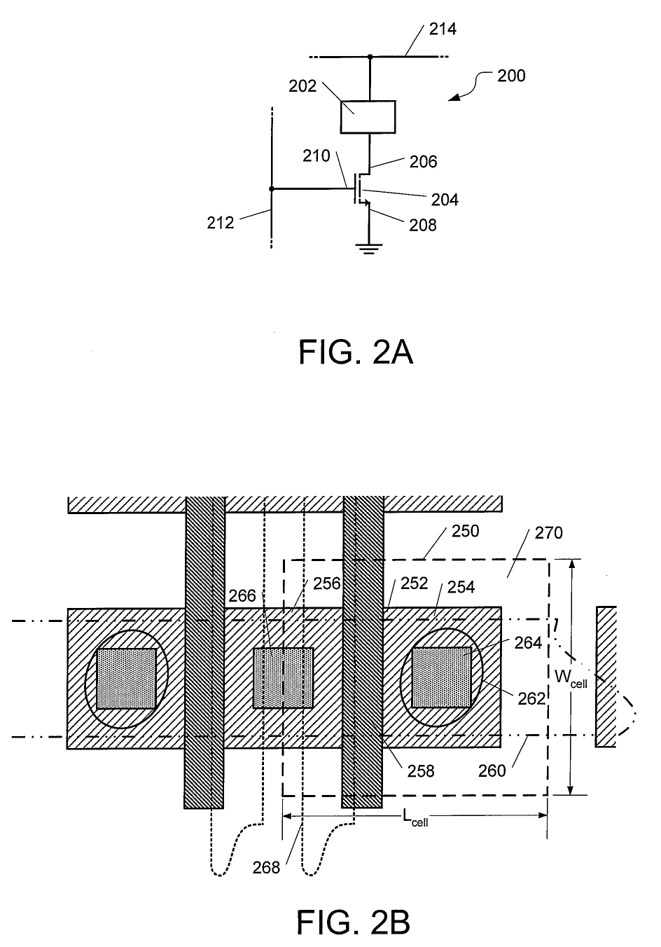

FIG. 2A illustrates a block diagram of a cell of a conventional thermal select MRAM device. A memory cell 200 includes a magnetic tunnel junction (MTJ) 202, electrically connected in series with a transistor 204. A source portion 206 of the transistor 204 is connected to the MTJ 202, a drain portion 208 of the transistor 204 is connected to ground, and a gate portion 210 of the transistor 204 is connected to a word line 212. A bit line 214 is electrically coupled to the MTJ 202. When the memory cell 200 is selected, a voltage on the word line 212 is applied to the gate portion 210 of the transistor 204, permitting current to flow from the bit line 214, through the MTJ 202 and the transistor 204. This current flow causes the heating of the MTJ 202, which permits a value to be written to the memory cell 200.

FIG. 2B illustrates an example layout for a conventional single transistor thermal select MRAM memory cell, such as is illustrated as a block diagram in FIG. 2A. For purposes of illustration, a 65 nm CMOS technology is used.

A memory cell 250 includes a transistor 252 having a source region 254, a drain region 256, and a gate 258. A bit line 260, in a metallization (M3) layer, is electrically connected to a magnetic tunnel junction (MTJ) 262, which is connected through a via connection 264 to the source region 254 of the transistor 252. The drain region 256 of the transistor 254 is electrically connected to a ground line (not illustrated) in a metallization (M1) layer (not illustrated) through a ground via connection 266. A word line 268 is electrically connected to the gate 258 of the transistor 252, so that a current may flow through the MTJ 260 and the transistor 252 when an activation voltage is applied on the word line 268. An isolation region 270 surrounds the transistor 252, electrically isolating the cell from other adjacent cells.

As can be seen in FIG. 2B, cell density is improved by sharing the drain region 256 and ground via connection 266 between the transistors of two adjacent cells. Thus, in measurements of the size of the memory cell 250, only half of the size of the drain region 256 and half of the size of the ground via connection 266 are included in the size of the cell 250.

In 65 nm CMOS technology, the overall width of the memory cell 250, W_{cell}, is approximately 300 nm. The length of the cell, L_{cell}, is approximately 325 nm. These sizes are determined by the minimum transistor width to handle the current necessary for writing to a thermal select MRAM cell, and by the size of the via contacts to the source region 254 and the drain region 256. In terms of the minimum feature size, F, of 65 nm, W_{cell} is 4.6 F, and L_{cell} is 5 F. This gives an overall cell area of 23 F².

In the cell design (250) described in FIG. 2B characterized by one transistor (252) per memory cell (250), the size of the ground via contacts to the source region 254 and the drain region 256 is determined by the photolithographic limit, resulting in a fairly large (23 F2) size of the cell. In other words, the large ground contact size (266) contributes to the large size of the cell (250).

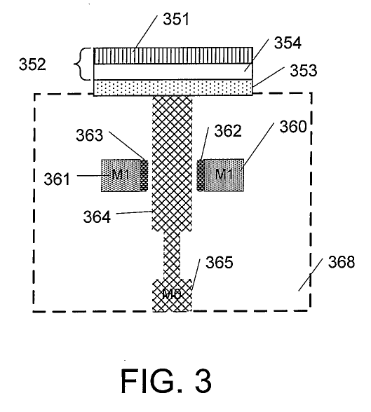

FIG. 3 schematically illustrate the method, disclosed by J. H. Park et al. at the IEDM in 2003 (“An 8 F² MRAM Technology using Modified Metal Lines”), of forming an 8 F² cell in 180 nm technology node for conventional Stoner Wohlfarth MRAM. A via 364 is positioned between two metal lines M1s 360 and 361 and a magnetic tunnel junction 352 in a substrate 368, having multiple layers 351 and 354, is located on the bottom electrode 353. The method includes the formation of a mask-defined contact through the creation of a Mb 0 365 level for contact landing (i.e. the contact landing in the M0 metallization level) and the employment of the M1 spacers 362 and 363 gap (i.e. the spacers in the M1 metallization level) to form an additional via etch above the conventional transistor cell. This method does not allow the contact size to be further scaled down below the design specification of the technology node because the definition of the M0 level depends on photolithography and thus on masks.

To achieve a chip density that is competitive with other memory technologies, such as DRAM, it is necessary to reduce the size of the memory cell. For example, in 65 nm technology, an MRAM cell should be smaller than 10 F2, where F is the minimum feature size (i.e., 65 nm) to be competitive. Therefore, it would be desirable to reduce the size of the cell by approximately a factor of two.

In accordance with one embodiment of the present invention, this is achieved by using a design in which each cell includes two transistors electrically connected in parallel, with a common source region, which provide a way for a via contact to be formed in a self-aligned manner, using the gate poly sidewall spacers. This self-aligned contact permits a reduction in cell size, since it is not necessary to provide extra space to allow for misalignments. Additionally, since the via contact does not depend on photolithography and thus on masks, the size of the contact can be reduced well below the design specification of the technology node, and the overall cell size can be reduced. Additionally, the use of a design in which each cell includes two transistors electrically connected in parallel increases the effective transistor width, thereby permitting a higher write current.

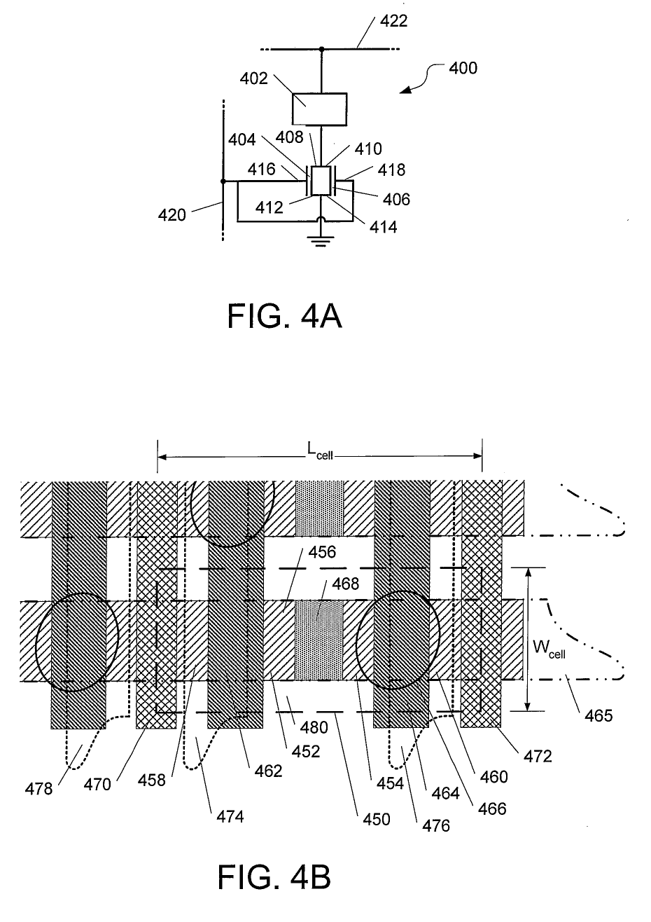

FIGS. 4A and 4B illustrate an embodiment of a thermal select MRAM cell constructed in accordance with the principles of the present invention. In FIG. 4A, a block diagram of a memory cell 400 is illustrated. The memory cell 400 includes a magnetic tunnel junction (MTJ) 402, electrically connected in series with transistors 404 and 406, which are connected in parallel. Source portions 408 and 410 of transistors 404 and 406 are connected to the MTJ 402, and drain portions 412 and 414 are connected to ground. Gate portions 416 and 418 of the transistors 404 and 406 are connected to a word line 420. A bit line 422 is electrically connected to the MTJ 402. When the memory cell 400 is selected, a voltage on the word line 420 is applied to the gate portions 416 and 418 of the transistors 404 and 406 permitting current to flow from the bit line 422, through the MTJ 402 and the transistors 404 and 406. This current flow causes the heating of the MTJ 302, which permits a value to be written to the memory cell 400.

FIG. 4B illustrates an example layout for a thermal select MRAM memory cell in accordance with an embodiment of the present invention, such as is illustrated as a block diagram in FIG. 4A. As before, for purposes of illustration, a 65 nm CMOS technology is used.

A memory cell 450 includes transistors 452 and 454, having a common source region 456, drain regions 458 and 460, and gates 462 and 464. A bit line 465, in a metallization layer, is electrically connected to a magnetic tunnel junction (MTJ) 466, which is connected through a self-aligned via connection 468 to the common source region 456 of the transistors 452 and 454. It should be noted that although the MTJ 466 is not illustrated as being located directly above the self-aligned via connection 468, they are electrically connected in a layer that is not illustrated in FIG. 4B. Generally, the MTJs in an MRAM device may be placed in an offset position, such as is illustrated in FIG. 4B.

The drain region 458 of the transistor 452 is electrically connected to a buried ground contact 470, and the drain region 460 of the transistor 454 is electrically connected to a buried ground contact 472.

A word line 474 is electrically connected to gates 462 and 464 of transistors 452 and 454, so that a current may flow through the MTJ 466 when an activation voltage is applied on the word line 474. A metal ground line 476, which, in this embodiment, runs in the same metallization layer as the word line 474, is connected with the buried ground contact 472 at intervals using via connections (not illustrated). In some embodiments, the metal ground lines 476 and 478 may also be used as word lines.

An isolation region 480 isolates rows of cells from adjacent rows of cells in the word line direction. The symmetric design of the cells, using two transistors per cell, permits the isolation regions between adjacent cells in the bit line direction to be eliminated, improving the memory cell density.

A further benefit of the layout illustrated in FIG. 4B is that the two transistors in parallel can facilitate the formation of via contacts in a self-aligned manner, using the gate poly sidewall spacers. As can be seen in FIG. 4B, each via connection is placed between two gates 462 and 464, the sidewall spacers of which may be used to align the via contacts. In this way, the length of the self-aligned via connection region 468, is defined by the distance between the two adjacent sidewall spacers (not illustrated) that are formed against the poly line structure of the gates 462 and 464, and do not depend on photolithography. The size of the self-aligned via connection region 468 can be therefore reduced well below the design specification of the technology node, and the overall cell size can be reduced

The self-aligned via connection region 468 is aligned with the active area of the transistors 452 and 454, and its width after the salicidation (self-aligned silicidation) corresponds to the width of the transistors 452 and 454.

As illustrated in FIG. 4B, the overall width of the memory cell 400, W_{cell}, is approximately 130 nm in 65 nm CMOS technology. The length of the cell, L_{cell}, is approximately 310 nm. These sizes are determined by the minimum transistor width to handle the current necessary for writing to a thermal select MRAM cell, and by the size of the self-aligned via connection region 468. In terms of the minimum feature size, F, of 65 nm, W_{cell} is 2.0 F, and L_{cell} is 4.77 F. This gives, for the cell 450 illustrated in FIG. 4B, an overall cell area of 9.54 F², which is significantly smaller than the cell size of 23 F² of the conventional art cell 250 illustrated in FIG. 2B to the same scale. The reduction of the cell size from 23 F² to 9.54 F² achieved by one embodiment of the present invention corresponds to an increase in the effective transistor width, which results in sufficient writing current required for thermal select MRAM in 65 nm node technology.

It will be understood by one skilled in the relevant arts that the layout illustrated in FIG. 4B is for illustrative purposes, and that a similar two transistor design with self-aligned via connection may be used in other types of memory devices. For example, a similar design could be used to reduce the size of a spin-injection MRAM device or a PCRAM device. It will further be understood that, in accordance with one embodiment of the present invention, similar designs may be employed in a variety of applications where high current and high density and/or small cell size are desirable. For example, a similar design can be used for diodes, power transistors, LCD applications, or a variety of non-volatile memory applications.

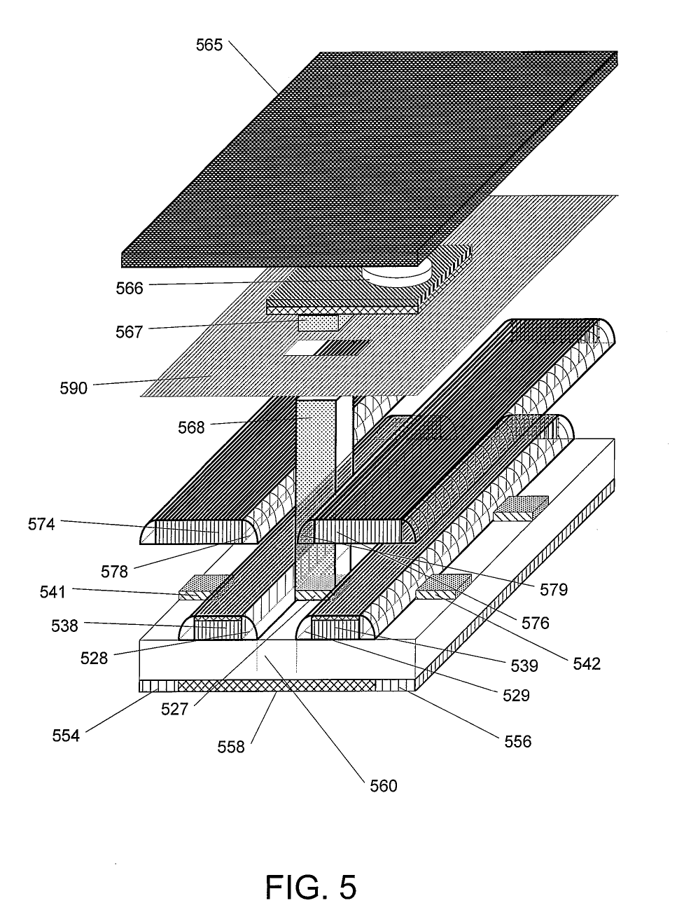

FIG. 5 illustrate a perspective view of the memory cell illustrated in FIGS. 4A and 4B.

At the base of the memory cell 550 there are two heavily doped n+ regions 554 and 556, which form buried ground contacts. This buried ground contact links the ground electrodes of transistors in adjacent cells in the word line direction. These n+ regions 554 and 556 may be formed, for example, by implantation of an N-type dopant, such as arsenic or phosphorus, at an appropriate angle and rotation. The n+ regions 554 and 556 are separated by a heavily doped p+ region 558 underneath a shallow trench isolation (STI) structure 560. The p+ region 558 may be formed by implantation of a p-type dopant, such as boron. Formation of the p+/n+ junction in the length direction can be achieved using a photolithographic mask during implantation. More than 1 F distance is kept between the two poly lines for the p+/n+ junction definition in the length direction. The p+ region 558 electrically isolates the ground contacts of the two transistors in a cell from each other. Additionally, the p+ region 558 may serve, in addition to the STI structure 560, to isolate adjacent memory cells in the word line direction.

A bit line 565, in a metallization layer, is electrically connected to the magnetic tunnel junction (MTJ) 566, which is connected through the self-aligned via connection 568 and through the silicide layer 527 to the common source region 526 of located directly underneath the silicide layer 527. It should be noted that the MTJ 566 is located directly above the self-aligned via connection 568, and it is electrically connected to it through the layer 567. Generally, the MTJs in an MRAM device may be placed in an offset position, such as is illustrated in FIG. 5.

As illustrated in FIG. 5, the via connection 568 is placed between the sidewall spacer 579 of the first metal ground line 576 and the sidewall spacer 578 of the second metal wordline 574. At the gate level the via connection 568 is placed between the sidewall spacer 529 of the first gate 539 and the sidewall spacer 528 of the second gate 538. The sidewall spacer 578 and 579 at the metal lines level and the sidewall spacers 528 and 529 at the gate level may be used to align the via contacts, wherein the gap between the sidewall the sidewall spacer 578 and 579 is larger than the gap between the sidewall spacers 528 and 529 at the gate level. It should be also noted that the sidewall spacer 578 and the sidewall spacer 528 vertically partially overlap. Additionally the sidewall spacer 579 and the sidewall spacer 529 vertically partially overlap as well.

The via connection 568 is achieved by etching the interlevel dielectric all the way from the metal lines level (metal ground line 576 and metal wordline 574) through the silicided contact area 541, 542 and 527. The sidewall spacer 578 and 579 at the metal lines level and the sidewall spacers 528 and 529 at the gate level are used as etching mask to etch the contact via connection 568. The use of the via mask 590 defines the width of the self-aligned contact etch in the width direction, aligned with the silicided contact area 527. It should be noted that the use of the above via mask 590 defining etch area is longer than the length of the self-aligned contact area in the length direction.

In an exemplary embodiment of the invention the sidewall spacers of the first gate 539, the sidewall spacer of the second gate 538, the sidewall spacers of the metal ground line 576 and the sidewall spacers of the metal wordline 574 are all formed of the same material, which can be silicon nitride (Si₃N₄), which should be different from the interlevel dielectric materials between the gate sidewall spacers and the metal spacers, which can be a thermal oxide of silicon, such as silicon oxide (SiO) or silicon dioxide (SiO₂).

The surface cap material used for the shallow trench isolation (STI) region 560, which can be silicon oxynitride (SiOₓN_{y}) or silicon nitride (Si₃N₄), should be distinguishable by VIA etch from the interlevel dielectric material interlevel dielectric materials between the gate sidewall spacers and the metal spacers (SiO or SiO₂).

The deep via connection 568 can be filled by a metal liner, such as titanium nitride, (TiN) and a metal such as tungsten (W), followed by planarization.

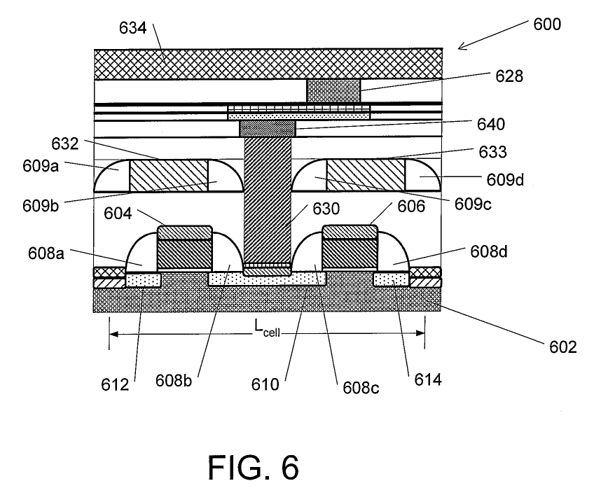

FIG. 6 illustrates a cross section of the memory cell design described in FIG. 4A, FIG. 4B and FIG. 5, illustrating the self-aligned via contacts of the two-transistor design. It should be noted that not all layers or connections are illustrated in FIG. 6, and there may be other layers or connections in the memory cell.

Cross-section 600 illustrates a substrate 602 that supports transistor gates 604 and 606, each of which defines a transistor. The gates 604 and 606 include sidewall spacers 608a÷608d. A metal ground line 633 and a metal wordline 632 lie in a second metallization layer, and they include sidewall spacers 609a÷609d.

At the gate level the gate sidewall spacers permit self-aligned contacts, including the contact with the shared source 610 and with the drains 612 and 614. The deep via connection 630 is placed between the sidewall spacer 608c of the first gate 606 and the sidewall spacer 608b of the second gate 604.

At the metal ground line and metal wordline level the deep via connection 630 is placed between the sidewall spacer 609c of the metal ground line 633 and the sidewall spacer 609b of the metal wordline 632. The deep via connection 630 is connected to an MTJ 628 through the layer 640. The MTJ 628 is electrically connected to a metal bit line 634 in a third metallization layer.

While the invention has been illustrated and described with reference to specific embodiments, it should be understood by those skilled in the art that various changes in form and detail may be made therein without departing from the spirit and scope of the invention as defined by the appended claims. The scope of the invention is thus indicated by the appended claims and all changes that come within the meaning and range of equivalency of the claims are intended to be embraced.

What is claimed is:

1. A transistor cell, comprising:
a first transistor having a first source/drain region, a first gate region, a second source/drain region and first gate spacers adjacent to the first gate region;
a second transistor having a third source/drain region, a second gate region, a fourth source/drain region and second gate spacers adjacent to the second gate region,
wherein the second source/drain region and the third source/drain region are connected with each other;
a first metal line above the first transistor;
first metal line spacers adjacent to the first metal line;
a second metal line above the second transistor;
second metal line spacers adjacent to the second metal line;
wherein the first metal line spacers and the first gate spacers vertically at least partially overlap;
wherein the second metal line spacers and the second gate spacers vertically at least partially overlap;
wherein a contact region is defined above the second source/drain region and/or the third source/drain region by a respective adjacent first metal line spacer and second metal line spacer and by a respective adjacent first gate spacer and second gate spacer; and
a contact via vertically extending from the contact region at least to the layer of the first metal line.

2. The transistor cell as claimed in claim 1, comprising wherein the first transistor and/or the second transistor is/are power transistor(s).

3. The transistor cell as claimed in claim 1, further comprising a storage element.

4. The transistor cell as claimed in claim 3, comprising wherein the storage element is a storage element being programmed by beans of electric current.

5. The transistor Transistor cell as claimed in claim 4, comprising wherein the storage element is a magnetoresistive storage element.

6. The transistor cell as claimed in claim 4, comprising wherein the storage element is a phase change storage element.

7. The transistor cell as claimed in claim 3, comprising wherein the contact via is connected to the storage element.

8. The transistor cell as claimed in claim 5, comprising a Magnetic Tunneling Junction element.

9. The transistor cell as claimed in claim 1, comprising wherein the first transistor and/or the second transistor is/are MOS transistor(s).

10. The transistor cell as claimed in claim 9, comprising wherein the first transistor and/or the second transistor is/are CMOS transistor(s).

11. The transistor cell as claimed in claim 9, comprising wherein the first transistor and/or the second transistor is/are BiCMOS transistor(s)

12. The transistor cell as claimed in claim 1, further comprising at least one additional metal line level comprising at least one further metal line above the first and second metal lines.

13. The transistor cell as claimed in claim 1, comprising wherein the first metal line and the second line are configured as word lines.

14. The transistor cell as claimed in claim 1, comprising wherein the metal line spacers and the gate spacers are made of the same material.

15. A method for manufacturing the transistor cell as claimed in claim 1, comprising:
providing the first transistor;
providing the second transistor;
providing the first metal line above the first transistor;
providing first metal line spacers adjacent to the first metal line, such that the first metal line spacers and the first gate spacers vertically at least partially overlap;
providing the second metal line above the second transistor;
providing second metal line spacers adjacent to the second metal line, such that the second metal line spacers and the second gate spacers vertically at least partially overlap;
forming the contact via on the contact region using the respective adjacent first metal line spacer and second metal line spacer, and the respective adjacent first gate spacer and second gate spacer as etching mask for etching the contact via hole; and
filling the contact via hole with contact via material.

16. The method as claimed in claim 15, comprising forming a storage element in a level above the metal lines.

17. The method as claimed in claim 16, comprising forming the storage element as a storage element being programmed by means of electric current.

18. The method as claimed in claim 17, comprising forming the storage element as a magnetoresistive storage element.

19. The method as claimed in claim 17, comprising forming the storage element as a phase change storage element.

20. The method as claimed in claim 18, comprising forming a Magnetic Tunneling Junction element in the storage element.

21. The method as claimed in claim 15, comprising making the metal line spacers and the gate spacers of the same material.

22. A memory cell, comprising:
a first transistor having a first source/drain region, a first gate region, a second source/drain region and first gate spacers adjacent to the first gate region;
a second transistor having a third source/drain region, a second gate region, a fourth source/drain region and second gate spacers adjacent to the second gate region;
wherein the second source/drain region and the third source/drain region are connected with each other;
a first metal line above the first transistor;
first metal line spacers adjacent to the first metal line;
a second metal line above the second transistor;
second metal line spacers adjacent to the second metal line;
wherein the first metal line spacers and the first gate spacers vertically at least partially overlap;
wherein the second metal line spacers and the second gate spacers vertically at least partially overlap;
wherein a contact region is defined above the second source/drain region and/or the third source/drain region by a respective adjacent first metal line spacer and second metal line spacer and by a respective adjacent first gate spacer and second gate spacer;
a contact via vertically extending from the contact region at least to the layer of the first metal line; and
a storage element, wherein the contact via is connected to the storage element.

23. The memory cell as claimed in claim 22, comprising wherein the storage element is a storage element being programmed by beans of electric current.

24. The memory cell as claimed in claim 23, comprising wherein the storage element is a magnetoresistive storage element.

25. A memory cell arrangement, comprising:
a plurality of memory cells, wherein each memory cell comprises:
a first transistor having a first source/drain region, a first gate region, a second source/drain region and first gate spacers adjacent to the first gate region;
a second transistor having a third source/drain region, a second gate region, a fourth source/drain region and second gate spacers adjacent to the second gate region;
wherein the second source/drain region and the third source/drain region are connected with each other;
a first metal line above the first transistor;
first metal line spacers adjacent to the first metal line;
a second metal line above the second transistor;
second metal line spacers adjacent to the second metal line;
wherein the first metal line spacers and the first gate spacers vertically at least partially overlap;
wherein the second metal line spacers and the second gate spacers vertically at least partially overlap;
wherein a contact region is defined above the second source/drain region and/or the third source/drain region by a respective adjacent first metal line spacer and second metal line spacer and by a respective adjacent first gate spacer and second gate spacer;
a contact via vertically extending from the contact region at least to the layer of the first metal line;
a storage element, wherein the contact via is connected to the storage element; and
a control circuit for reading and/or writing information from and/or into the storage element.

26. A memory, comprising:
a first metal line above a first transistor having a first gate spacer;
first metal line spacers adjacent to the first metal line;
a second metal line above a second transistor having a second gate spacer;
second metal line spacers adjacent to the second metal line;
wherein the first metal line spacers and the first gate spacers vertically at least partially overlap;
wherein the second metal line spacers and the second gate spacers vertically at least partially overlap;
wherein a contact region is defined above a second transistor source/drain region and/or a third transistor source/drain region by a respective adjacent first metal line spacer and second metal line spacer and by a respective adjacent first gate spacer and second gate spacer;
a contact via vertically extending from the contact region at least to the layer of the first metal line; and
a storage element connected to the contact via.

27. A memory, comprising:
a first metal line above a first transistor having a first gate spacer;
first metal line spacers adjacent to the first metal line;
a second metal line above a second transistor having a second gate spacer;
second metal line spacers adjacent to the second metal line;
wherein the first metal line spacers and the first gate spacers vertically at least partially overlap;
wherein the second metal line spacers and the second gate spacers vertically at least partially overlap;
wherein a contact region is defined above a second transistor source/drain region and/or a third transistor source/drain region by a respective adjacent first metal line spacer and second metal line spacer and by a respective adjacent first gate spacer and second gate spacer;
means for providing a contact via vertically extending from the contact region at least to the layer of the first metal line; and
means for providing a storage element connected to the contact via.
